(19) United States
(12) Patent Application Publication
(10) Pub. No.: US 2022/0301865 A1
(43) Pub. Date: Sep. 22, 2022

(54) SUBSTRATE PROCESSING APPARATUS, REACTION TUBE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Atsushi HIRANO, Toyama-shi (JP)

(73) Assignee: KOKUSAI ELECTRIC CORPORATION, Tokyo (JP)

(21) Appl. No.: 17/825,393

(22) Filed: May 26, 2022

Related U.S. Application Data
(63) Continuation-in-part of application No. PCT/JP2020/003022, filed on Jan. 28, 2020.

(51) Int. Cl. H01L 21/02; H01L 21/673; H01L 21/687; C23C 16/34; C23C 16/458

(52) U.S. Cl. CPC H01L 21/02271; H01L 21/0217; H01L 21/67303; H01L 21/68764; C23C 16/345; C23C 16/4584

(57) ABSTRACT

There is provided a technique that includes a substrate holder configured to arrange and hold substrates; and a reaction tube in which the substrate holder is accommodated. The substrate holder includes a plurality of pillars installed around the arranged substrates and extending in a direction substantially perpendicular to the substrates, a top plate configured to fix one ends of the pillars to each other and having an opening at a center of the top plate, and a bottom plate configured to fix other ends of the pillars to each other. The reaction tube includes a protrusion protruding inward. The protrusion is installed to be inserted into the opening of the top plate in a state where the substrate holder is accommodated in the reaction tube, and is configured to be closer to a substrate arranged closest to the top plate of the substrate holder than the top plate.

### CROSS-REFERENCE TO RELATED APPLICATION

This application is a Bypass Continuation-in-Part Application of PCT International Application No. PCT/JP2020/003022, filed on Jan. 28, 2020, the entire content of which is incorporated herein by reference.

### TECHNICAL FIELD

The present disclosure relates to a substrate processing apparatus, a reaction tube, a method of manufacturing a semiconductor device, and a recording medium.

### BACKGROUND

In the related art, there is known a substrate processing apparatus that forms a film on the surface of each of the substrates in a state in which the substrates are held in multiple stages by a substrate holder in a process furnace.

In order to safely load and unload the substrate holder into and from the process furnace and to rotate the substrate holder, it is necessary to form a gap between a top plate of the substrate holder and an inner surface of a reaction tube that constitutes a process furnace for accommodating the substrate holder. Further, a product substrate used as a product has a larger surface area than a monitoring substrate or a dummy substrate not used as a product. Therefore, consumption of a processing gas when processing the product substrate is large.

Therefore, the uniformity of the formed film may deteriorate by an excess gas generated in the gap between the top plate of the substrate holder and the inner surface of the reaction tube. Such deterioration of the uniformity is called a loading effect.

### SUMMARY

Some embodiments of the present disclosure provide a technique capable of improving the inter-plane/in-plane uniformity of a film formed on a substrate.

According to embodiments of the present disclosure, there is provided a technique that includes a substrate holder configured to arrange and hold substrates; and a reaction tube in which the substrate holder is accommodated, wherein the substrate holder includes a plurality of pillars installed around the arranged substrates and extending in a direction substantially perpendicular to the substrates, a top plate configured to fix one ends of the pillars to each other and having an opening at a center of the top plate, and a bottom plate configured to fix other ends of the pillars to each other, wherein the reaction tube includes a protrusion protruding inward in a shape corresponding to a shape of the opening of the top plate and having a flat leading end, and wherein the protrusion is installed to be inserted into the opening of the top plate in a state where the substrate holder is accommodated in the reaction tube, and is configured to be closer to a substrate arranged closest to the top plate of the substrate holder than the top plate.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus 101 according to embodiments of the present disclosure.

FIG. 2 is a side sectional view of a process furnace 202 according to embodiments of the present disclosure.

FIG. 3 is a diagram showing a control flow according to embodiments of the present disclosure.

FIG. 4 is a perspective view of a substrate holder according to embodiments of the present disclosure.

FIG. 5 is a perspective view showing a relationship between a substrate holder and an inner tube according to embodiments of the present disclosure.

FIG. 6A is a side sectional view for explaining a relationship between a substrate holder and an inner tube according to embodiments of the present disclosure, and FIG. 6B is an enlarged view for explaining a periphery of a recess 204c shown in FIG. 6A.

FIG. 7 is a side sectional view showing a modification of an inner tube according to embodiments of the present disclosure.

FIG. 8 is a side sectional view showing a modification of a reaction tube according to embodiments of the present disclosure.

FIG. 9A is a diagram showing distribution of a SiCl₂ partial pressure in a process furnace when a Si₂Cl₆ gas is supplied to a wafer using a process furnace according to a Comparative Example, and FIG. 9B is a diagram showing distribution of a SiCl₂ partial pressure in a process furnace 202 when a Si₂Cl₆ gas is supplied to a wafer using a process furnace 202 according to a Present Example.

FIG. 10A is a diagram showing the wafer inter-plane uniformity that evaluates the average value of the SiCl₂ partial pressures on the wafers at the respective slot numbers when a Si₂Cl₆ gas is supplied onto the wafers using the process furnace according to a Comparative Example and the process furnace 202 according to a Present Example, and FIG. 10B is a diagram showing the wafer in-plane uniformity that compares the numerical values obtained by dividing the difference between the center and the end of each of the wafers at the respective slot numbers by an average value when a Si₂Cl₆ gas is supplied onto the wafers using the process furnace according to a Comparative Example and the process furnace 202 according to a Present Example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### EMBODIMENTS OF THE PRESENT DISCLOSURE

Hereinafter, embodiments of the present disclosure will be described.

### (1) Configuration of Substrate Processing Apparatus

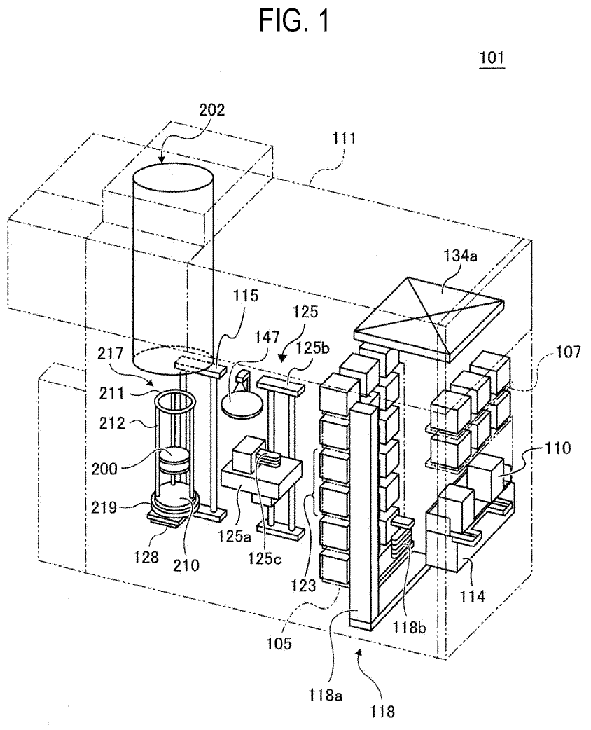

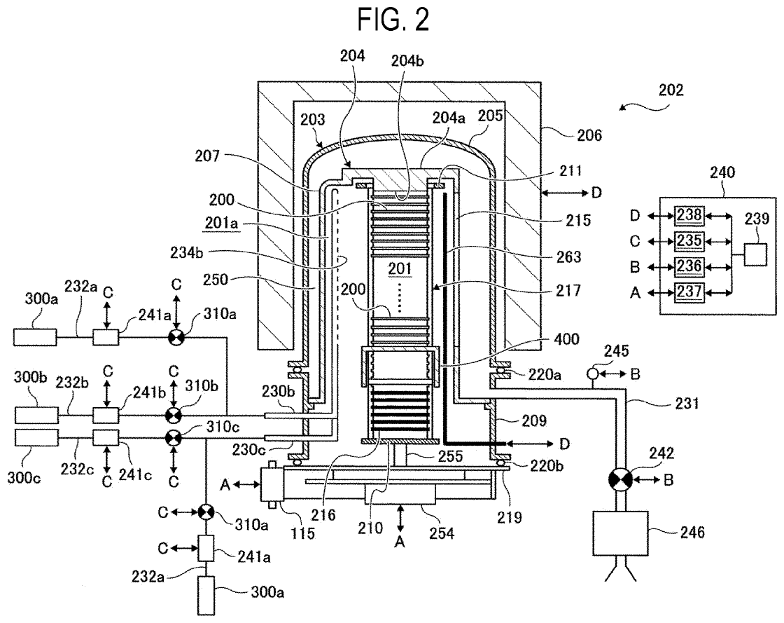

First, the configuration of the substrate processing apparatus 101 according to the present embodiments will be described with reference to FIGS. 1 and 2. FIG. 1 is a schematic configuration diagram of the substrate processing apparatus 101 according to embodiments of the present disclosure. FIG. 2 is a side sectional view of the process furnace 202 according to embodiments of the present disclosure. The substrate processing apparatus 101 according to the present embodiments is configured as a vertical apparatus that performs oxidation, diffusion treatment, thin film formation, and the like on substrates such as wafers or the like.

### (Overall Structure)

As shown in FIG. 1, the substrate processing apparatus 101 is configured as a batch type vertical heat treatment apparatus. The substrate processing apparatus 101 includes a housing 111 in which a main portion such as a process furnace 202 or the like is installed. A pod (also referred to as a FOUP) 110 is used as a substrate transfer container (wafer carrier) to be loaded into the housing 111. The pod 110 is configured to accommodate, for example, 25 wafers 200 as substrates made of silicon (Si), silicon carbide (SiC), or the like. A pod stage 114 is arranged on the front side of the housing 111. The pod 110 is configured to be placed on the pod stage 114 with the lid thereof closed.

A pod transfer device 118 is provided at a position on the front side (right side in FIG. 1) in the housing 111 facing the pod stage 114. In the vicinity of the pod transfer device 118, a pod mounting shelf 105, a pod opener (not shown), and a wafer number detector (not shown) are installed. The pod mounting shelf 105 is arranged above the pod opener and is configured to hold a plurality of pods 110 in a mounted state. The wafer number detector is installed adjacent to the pod opener. The pod transfer device 118 includes a pod elevator 118a that can move up and down while holding the pod, and a pod transfer mechanism 118b as a transfer mechanism. The pod transfer device 118 is configured to transfer the pod 110 between the pod stage 114, the pod mounting shelf 105, and the pod opener by the continuous operation of the pod elevator 118a and the pod transfer mechanism 118b. The pod opener is configured to open the lid of the pod 110. The wafer number detector is configured to detect the number of wafers 200 in the pod 110 with the lid opened.

A wafer transfer machine 125 and a boat 217 as a substrate holder are provided in the housing 111. The wafer transfer machine 125 includes an arm (tweezer) 125c and has a structure capable of being raised or lowered in the vertical direction and rotated in the horizontal direction by a driving means (not shown). The arm 125c is configured to take out, for example, five wafers at the same time. By moving the arm 125c, the wafer 200 is transferred between the pod 110 placed at the position of the pod opener and the boat 217.

Next, the operation of the substrate processing apparatus 101 according to the present embodiments will be described.

First, the pod 110 is placed on the pod stage 114 by an in-process transfer device (not shown) such that the wafers 200 take a vertical posture and the wafer loading/unloading port of the pod 110 faces upward. Thereafter, the pod 110 is rotated by 90 degrees in a vertical direction toward the rear side of the housing 111 by the pod stage 114. As a result, the wafers 200 in the pod 110 take a horizontal posture, and the wafer loading/unloading port of the pod 110 faces rearward in the housing 111.

Next, the pod 110 is automatically transferred to a designated shelf position of the pod mounting shelf 105 by the pod transfer device 118, delivered to the pod mounting shelf 105, and temporarily stored on the pod mounting shelf 105. Then, the pod 110 is delivered from the pod mounting shelf 105 to the pod opener or transferred directly to the pod opener.

When the pod 110 is transferred to the pod opener, the lid of the pod 110 is opened by the pod opener. Then, the number of wafers in the pod 110 with the lid opened is detected by the wafer number detector. The wafer 200 is picked up from an inside of the pod 110 by the arm 125c of the wafer transfer machine 125 through the wafer loading/unloading port and is charged into the boat 217 by the transfer operation of the wafer transfer machine 125. The wafer transfer machine 125 that has delivered the wafer 200 to the boat 217 returns to the pod 110 and charges the next wafer 200 into the boat 217.

When a predetermined number of wafers 200 is charged into the boat 217, the lower end portion of the process furnace 202 closed by the furnace opening shutter 147 is opened by the furnace opening shutter 147. Subsequently, the seal cap 219 is raised by the boat elevator 115 (see FIG. 2), so that the boat 217 holding the group of wafers 200 is loaded into the process furnace 202 (boat loading). After loading the boat 217, arbitrary processing is performed on the wafers 200 in the process furnace 202. Such processing will be described later. After the processing, the wafers 200 and the boat 217 are unloaded from the process furnace 202 (boat unloading), the wafers 200 are discharged from the boat 217 in the reverse procedure of the above procedure and are moved to the outside of the housing 111.

### (Configuration of Process Furnace)

Subsequently, the configuration of the process furnace 202 according to the present embodiments will be described with reference to FIG. 2.

### (Process Chamber)

As shown in FIG. 2, the process furnace 202 includes a reaction tube (tubular reactor) 203 constituting a process vessel. The reaction tube 203 includes an inner tube 204 and an outer tube 205 installed on the outer side of the inner tube 204. The inner tube 204 is made of a heat-resistant material such as quartz (SiO₂) or silicon carbide (SiC). As will be described in detail later, the inner tube 204 is formed in a cylindrical shape with the upper end thereof closed and the lower end thereof opened. The inner tube 204 forms a process chamber 201 in which a thin film is formed on a wafer 200. The process chamber 201 is configured to accommodate wafers 200 in a state in which they are aligned and held in multiple stages in the vertical direction in a horizontal posture by a boat 217. The inner tube 204 includes at least one bulging portion 207 that extends from the outer peripheral surface thereof toward the outer tube 205 and is formed such that the side surface thereof bulges outward. A nozzle chamber 201a extending in the vertical direction is formed in the bulging portion 207. The nozzle chamber 201a is configured to accommodate nozzles 230b and 230c to be described later. Further, the inner tube 204 includes a discharge port 215 opened at a position facing the arranged wafers on the outer peripheral surface opposite to the nozzle chamber 201a and configured to allow an atmosphere to flow out into a tubular space 250 between the inner tube 204 and the outer tube 205.

The outer tube 205 has a pressure-resistant structure and airtightly accommodates the inner tube 204. Further, the outer tube 205 may be provided concentrically with the inner tube 204. The outer tube 205 has an inner diameter larger than the outer diameter of the inner tube 204 and is formed in a cylindrical shape with the upper end thereof closed and the lower end thereof opened. The outer tube 205 is made of a heat-resistant material such as quartz or silicon carbide. In such a reaction tube configuration, the gas flow (convective flow) formed in parallel to the respective surfaces of the wafers 200 is dominantly responsible for the movement of materials to the vicinity of the surfaces of the wafers 200. At this time, the reaction tube 203 is called a cross-flow reaction tube.

### (Nozzle)

The nozzles 230b and 230c extend in parallel with the arrangement axis (arrangement direction) of the wafers 200 and are arranged in the bulging portion 207. The nozzle 230b and the nozzle 230c may be installed in an arcuate space between the inner wall of the inner tube 204 and the wafers 200. Each of the nozzle 230b and the nozzle 230c may be composed of a U-shaped and linear quartz pipe having a closed leading end. Gas supply holes 234b and gas supply holes 234c as gas supply ports for supplying gases to each of the arranged wafers 200 are formed on the side surfaces of the nozzles 230b and the nozzles 230c. The gas supply holes 234b and 234c have the same opening area or gradually changing opening areas from the lower portion to the upper portion and are installed at the same pitch. The upstream ends of the nozzle 230b and the nozzle 230c are connected to the downstream ends of the gas supply pipe 232b and the gas supply pipe 232c, respectively. Further, the nozzles 230b and 230c are configured not to have gas supply holes 234b and 234c at positions corresponding to a plurality of arrangement positions surrounded by a cover 400 to be described later. Moreover, the nozzles 230b and 230c are configured to have gas supply holes 234b and 234c at positions corresponding to a plurality of wafers 200 such as product substrates or monitoring substrates held at a plurality of arrangement positions between the cover 400 and the top plate 211 to be described later. In such process chamber and nozzle configurations, the gas flow (convective flow) formed in parallel to the respective surfaces of the wafers 200 is dominantly responsible for the movement of materials to the vicinity of the surfaces of the wafers 200. At this time, the reaction tube 203 is called a cross-flow reaction tube.

### (Heater)

On the outside of the reaction tube 203, a heater 206 as a furnace body is installed concentrically to surround the side wall surface and the ceiling surface of the reaction tube 203. The heater 206 is formed in a cylindrical shape. The heater 206 is vertically installed by being supported on a heater base as a holding plate (not shown). A temperature sensor 263 as a temperature detector is installed in the reaction tube 203 (e.g., between the inner tube 204 and the outer tube 205, the inside of the inner tube 204, etc.). A temperature controller 238, which will be described later, is electrically connected to the heater 206 and the temperature sensor 263. The temperature controller 238 is configured to control the degree of supplying power to the heater 206 at a predetermined timing based on the temperature information detected by the temperature sensor 263 so that the temperature in the process chamber 201 has a predetermined temperature distribution.

### (Manifold)

Below the outer tube 205, a manifold (inlet adapter) 209 is arranged concentrically with the outer tube 205. The manifold 209 is made of, for example, stainless steel. The manifold 209 is formed in a cylindrical shape with open upper and lower ends. The manifold 209 is installed so as to engage with the lower end of the inner tube 204 and the lower end of the outer tube 205 or to support the lower end of the inner tube 204 and the lower end of the outer tube 205. An O-ring 220a as a sealing member is provided between the manifold 209 and the outer tube 205. As the manifold 209 is supported by the heater base (not shown), the reaction tube 203 comes into a vertically installed state. A process vessel is mainly formed by the reaction tube 203 and the manifold 209.

### (Boat)

A boat 217 as a substrate holder is configured to be loaded into and accommodated in the reaction tube 203 and the process chamber 201 from below the lower end opening of the manifold 209. The boat 217 is made of a heat-resistant material such as quartz or silicon carbide. As will be described in detail later, the boat 217 includes is a plurality of, for example, three pillars 212, a ring-shaped top plate 211 having an opening at the center thereof and configured to fix the upper ends of the three pillars 212 to each other, and a disk-shaped bottom plate 210 configured to fix the lower ends of the three pillars 212 to each other. The boat 217 is configured to arrange and hold a plurality of wafers 200 at predetermined intervals in a horizontal posture with the centers of the wafers 20 aligned with each other. Further, the boat 217 is configured to arrange and hold a plurality of disk-shaped heat insulating plates 216 as heat insulating members at predetermined intervals in a horizontal posture with the centers of the heat insulating plates 216 aligned with each other. The heat insulating plates 216 are made of a heat-resistant material such as quartz or silicon carbide. The heat insulating plate 216 are configured such that it is difficult to transfer the heat from the heater 206 to the manifold 209,

Further, a cover 400 for covering the periphery of the boat 217 is provided below the boat 217 and above the heat insulating region in which the heat insulating plates 216 are stacked below the wafer processing region. The cover 400 surrounds a plurality of arrangement positions, which include an arrangement position closest to the bottom plate 210 among the arrangement positions (also referred to as stacking positions) of the wafers 200 in the boat 217, from the upper surface and the side surface of the plurality of arrangement positions. The boat 217 does not hold the wafers 200 such as product substrates or monitoring substrates at a plurality of arrangement positions surrounded by the cover 400. These arrangement positions may correspond to the positions where dummy substrates are arranged since sufficient uniformity cannot be obtained in the past. In addition, the boat 217 is configured to hold a plurality of wafers 200 such as product substrates or monitoring substrates at a plurality of arrangement positions between the cover 400 and the top plate 211.

### (Carrier Gas Supply System)

On the side wall of the manifold 209, nozzles 230b and nozzles 230c for supplying, for example, a nitrogen (N₂) gas as a carrier gas into the process chamber 201 are installed so as to communicate with the inside of the process chamber 201. On the gas supply pipe 232a, a carrier gas source 300a, a mass flow controller 241a as a flow rate controller (flow rate control means), and a valve 310a are installed sequentially from the upstream side. With the above configuration, it is possible to control the supply flow rate of the carrier gas supplied into the process chamber 201 via the gas supply pipe 232a, and the concentration or partial pressure of the carrier gas in the process chamber 201.

A gas flow rate controller 235, which will be described later, is electrically connected to the valve 310a and the mass flow controller 241a. The gas flow rate controller 235 is configured to control the start and stop of the carrier gas supply into the process chamber 201, the supply flow rate, and the like at predetermined timings.

A carrier gas supply system according to the present embodiments is mainly composed of the valve 310a, the mass flow controller 241a, the gas supply pipe 232a, the gas supply pipe 232b, the nozzle 230b, the gas supply pipe 232c, and the nozzle 230c. In addition, the carrier gas supply system may include the carrier gas source 300a.

### (Si Precursor Gas Supply System)

On the side wall of the manifold 209, a nozzle 230b for supplying, for example, a hexachlorodisilane (Si₂Cl₆ which is abbreviated as HCDS) gas as an example of a precursor gas (Si-containing gas) is installed so as to communicate with the inside of the process chamber 201. The upstream end of the nozzle 230b is connected to the downstream end of the gas supply pipe 232b. On the gas supply pipe 232b, a Si precursor gas source 300b, a mass flow controller 241b and a valve 310b are installed sequentially from the upstream side. With the above configuration, it is possible to control the supply flow rate of the Si precursor gas supplied into the process chamber 201, and the concentration or partial pressure of the Si precursor gas in the process chamber 201.

A gas flow rate controller 235, which will be described later, is electrically connected to the valve 310b and the mass flow controller 241b. The gas flow rate controller 235 is configured to control the start and stop of the supply of the Si precursor gas into the process chamber 201, the supply flow rate, and the like at predetermined timings.

A Si precursor gas supply system according to the present embodiments is mainly composed of the valve 310b, the mass flow controller 241b, the gas supply pipe 232b, and the nozzle 230b. In addition, the Si precursor gas supply system may include the Si precursor gas source 300b.

### (Nitriding Precursor Gas Supply System)

On the side wall of the manifold 209, a nozzle 230c for supplying, as an example of a modifying precursor (reaction gas or reactant), a gas such as ammonia (NH₃), nitrogen (N²), nitrous oxide (N₂O), monomethylhydrazine (CH₆N₂) or the like, which is a nitriding precursor gas, is installed so as to communicate with the inside of the process chamber 201. The upstream end of the nozzle 230c is connected to the downstream end of the gas supply pipe 232c. On the gas supply pipe 232c, a nitriding precursor gas source 300c, a mass flow controller 241c and a valve 310c are installed sequentially from the upstream side. With the above configuration, it is possible to control the supply flow rate of the nitriding precursor gas supplied into the process chamber 201, and the concentration or partial pressure of the nitriding precursor gas in the process chamber 201.

A gas flow rate controller 235, which will be described later, is electrically connected to the valve 310c and the mass flow controller 241c. The gas flow rate controller 235 is configured to control the start and stop of the nitriding precursor gas supply into the process chamber 201, the supply flow rate, and the like at predetermined timings.

A nitriding precursor gas supply system according to the present embodiments is mainly composed of the valve 310c, the mass flow controller 241c, the gas supply pipe 232c, and the nozzle 230c. In addition, the nitriding precursor gas supply system may include the nitriding precursor gas source 300c.

A gas supply system according to the present embodiments is mainly composed of the Si precursor gas supply system, the nitrided precursor gas supply system, and the carrier gas supply system.

### (Exhaust System)

An exhaust pipe 231 for exhausting the inside of the process chamber 201 is installed on the side wall of the manifold 209. The exhaust pipe 231 penetrates the side surface portion of the manifold 209 and communicates with the lower end portion of the tubular space 250 which is an exhaust space formed by the gap between the inner tube 204 and the outer tube 205. On the downstream side of the exhaust pipe 231 (the side opposite to the side connected to the manifold 209), a pressure sensor 245 as a pressure detector, an APC (Auto Pressure Controller) valve 242 as a pressure regulator, and a vacuum pump 246 are installed sequentially from the upstream side.

A pressure controller 236, which will be described later, is electrically connected to the pressure sensor 245 and the APC valve 242. The pressure controller 236 is configured to control the opening degree of the APC valve 242 based on the pressure information detected by the pressure sensor 245 so that the pressure in the process chamber 201 becomes a predetermined pressure (vacuum degree) at a predetermined timing. The APC valve 242 is an opening/closing valve that is capable of being opened and closed to start and stop the exhaust of the inside of the process chamber 201 and is possible to regulate the pressure by adjusting the valve opening degree thereof.

An exhaust system according to the present embodiments is mainly composed of the exhaust pipe 231, the pressure sensor 245 and the APC valve 242. The exhaust system may include the vacuum pump 246 and may further include a trap device or a detoxifying device.

### (Seal Cap)

A seal cap 219 as a lid capable of airtightly closing the opening for loading and unloading the boat 217 into and out of the process vessel is installed in the lower end opening of the manifold 209. The seal cap 219 is made of a metal such as stainless steel or the like and is formed in a disk shape. An O-ring 220b as a sealing member to be joined with the lower end of the manifold 209 is installed on the upper surface of the seal cap 219. The seal cap 219 is configured to abut against the lower end of the manifold 209 from the lower side in the vertical direction of the reaction tube with the O-ring 220b sandwiched between the seal cap 219 and the manifold 209. The O-ring 220b seals a gas between the reaction tube 203 and the seal cap 219 without allowing the seal cap 219 to directly contact the reaction tube 203. The O-ring 220b can perform sufficient sealing when pressed to a desired crushing amount. The preferred crushing amount may vary depending on the deterioration of the O-ring 220b and is smaller than the arrangement spacing of the wafers 200. Direct contact between the manifold 209 and the seal cap 219 generates particles, which is not preferable. Therefore, a cushion member having no sealing property may be provided on the outer periphery of the O-ring 220b.

### (Rotation Mechanism)

Below the seal cap 219 (i.e., on the side opposite to the process chamber 201), a rotation mechanism 254 for rotating the boat 217 is installed. The rotation mechanism 254 holds the boat 217. A rotary shaft 255 included in the rotation mechanism 254 is installed so as to penetrate the seal cap 219. The upper end of the rotary shaft 255 rotatably supports the boat 217 from below. By operating the rotation mechanism 254, it is configured to capable of rotating the boat 217 and the wafers 200 in the process chamber 201. In order to make the rotary shaft 255 difficult to be affected by a process gas, an inert gas supply system (not shown) allows an inert gas to flow in the vicinity of the rotary shaft 255 to protect the rotary shaft 255 from the process gas.

### (Boat Elevator)

The seal cap 219 is configured to be raised or lowered in the vertical direction by a boat elevator 115 as an elevating mechanism installed vertically on the outside of the reaction tube 203. By operating the boat elevator 115, it is configured to capable of loading and unloading the boat 217 into and out of the process chamber 201 (boat loading or unloading).

A drive controller 237 is electrically connected to the rotation mechanism 254 and the boat elevator 115. The drive controller 237 is configured to control the rotation mechanism 254 and the boat elevator 115 at a predetermined timing so as to perform a predetermined operation.

### (Controller)

The gas flow rate controller 235, the pressure controller 236, the drive controller 237, and the temperature controller 238 described above are electrically connected to a main controller 239 that controls the entire substrate processing apparatus 101. A controller 240 as a control part according to the present embodiments is mainly composed of the gas flow rate controller 235, the pressure controller 236, the drive controller 237, the temperature controller 238, and the main controller 239.

The controller 240 is an example of a control part (control means) that controls the overall operations of the substrate processing apparatus 101, such as the flow rate control operations of the mass flow controllers 241a, 241b and 241c, the opening/closing operations of the valves 310a, 310b and 310c, the opening/closing operations of the APC valve 242, the pressure regulation operation based on the pressure sensor 245, the temperature adjustment operation of the heater 206 based on temperature sensor 263, the start/stop of the vacuum pump 246, the rotation speed adjustment of rotation mechanism 254, the raising/lowering operation of boat elevator 115, and the like.

### (2) Method of Manufacturing Semiconductor Device

Next, an example of a method of forming an insulating film on a wafer 200 when manufacturing a large-scale integrated (LSI) circuit or the like will be described as a process of manufacturing a semiconductor device by using the process furnace 202 of the substrate processing apparatus 101 described above. In the following description, the operation of each part constituting the substrate processing apparatus 101 is controlled by the controller 240.

In the present embodiments, a method of forming a SiN film, which is a silicon nitride film, on a wafer 200 will be described. First, a Si precursor gas and a reaction gas (nitriding precursor gas) are alternately supplied to form a SiN film on the wafer 200. In the present embodiments, an example in which a Si₂Cl₆ gas is used as the Si precursor gas and an NH₃ gas is used as the nitriding precursor gas that is the reaction gas will be described.

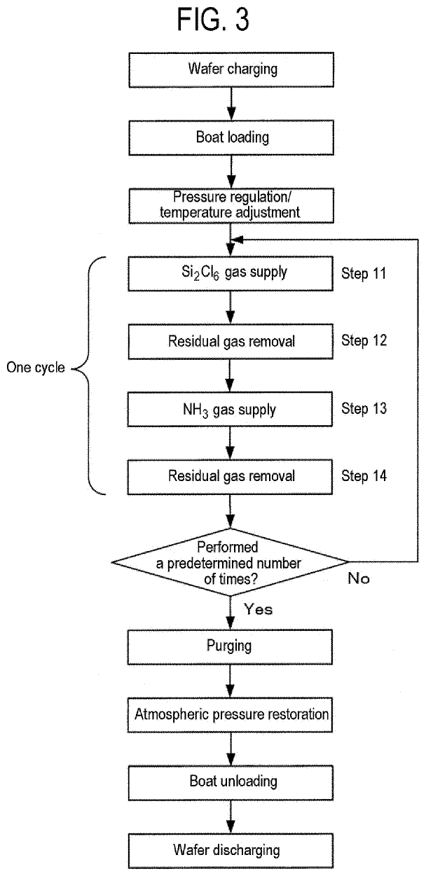

FIG. 3 shows an example of the control flow in the present embodiments. First, when a plurality of wafers 200 is charged into the boat 217 (wafer charging), the boat 217 charged with the plurality of wafers 200 is raised by the boat elevator 115 and loaded into the process chamber 201 (boat loading). The boat 217 charged with the plurality of wafers 200 is accommodated inside the reaction tube 203. In this state, the seal cap 219 seals the lower end of the reaction tube 203 via the O-ring 220b. Further, in the film-forming process, the controller 240 controls the substrate processing apparatus 101 as follows. That is, the inside of the process chamber 201 is maintained at a temperature of the range of, for example, 300 degrees C. to 600 degrees C., for example, 600 degrees C. by controlling the heater 206. Thereafter, the boat 217 is rotated by the rotation mechanism 254 to rotate the wafers 200. Thereafter, the vacuum pump 246 is operated and the APC valve 242 is opened to exhaust the inside of the process chamber 201. After the temperature of the wafers 200 reaches 600 degrees C. and thus the temperature and the like are stabilized, the steps described later are sequentially executed while keeping the temperature inside the process chamber 201 at 600 degrees C., to perform a process of processing the wafers 200.

### (Step 11)

In step 11, a Si₂Cl₆ gas is allowed to flow. Si₂Cl₆ is a liquid at the room temperature and may be supplied into the process chamber 201 by a method of supplying a Si₂Cl₆ gas after heating and vaporizing the same, or a method of using a vaporizer (not shown) to allow an inert gas such as He (helium), Ne (neon), Ar (argon) or N₂ (nitrogen), which is called a carrier gas, to pass through a container containing a Si₂Cl₆ gas and supplying vaporized Si₂Cl₆ gas to the process chamber 201 together with the carrier gas. The latter case will be described by way of example.

The Si₂Cl₆ gas is allowed to flow through the gas supply pipe 232b, and the carrier gas (N₂ gas) is allowed to flow through the carrier gas supply pipe 232a connected to the gas supply pipe 232b. The valve 310b of the gas supply pipe 232b, the valve 310a of the carrier gas supply pipe 232a connected to the nozzle 230b, and the APC valve 242 of the exhaust pipe 231 are all opened. The carrier gas is allowed to flow from the carrier gas supply pipe 232a and is flow-rate-adjusted by the mass flow controller 241a. The Si₂Cl₆ gas is allowed to flow from the gas supply pipe 232b, is flow-rate-adjusted by the mass flow controller 241b, is vaporized by the vaporizer (not shown), is mixed with the flow-rate-adjusted carrier gas, is supplied into the process chamber 201 from the gas supply holes 234b of the nozzle 230b and is exhausted from the exhaust pipe 231. At this time, the APC valve 242 is appropriately adjusted to maintain the pressure in the process chamber 201 in the range of 20 to 60 Pa, for example, at 53 Pa. The supply amount of the Si₂Cl₆ gas controlled by the mass flow controller 241b is 0.3 slm. At the same time, a N₂ gas as a carrier gas is supplied from the carrier gas supply pipe 232a connected to the gas supply pipe 232b. The supply flow rate of the N₂ gas controlled by the mass flow controller 241a of the carrier gas supply pipe 232a connected to the gas supply pipe 232b is, for example, 1 slm. The time for exposing the wafers 200 to the Si₂Cl₆ gas is 3 to 10 seconds. At this time, the temperature of the heater 206 is set such that the temperature of the wafers is in the range of 300 degrees C. to 600 degrees C., for example, 600 degrees C.

At this time, the gases flowing into the process chamber 201 are only the Si₂Cl₆ gas and the inert gas such as a N₂ gas, an Ar gas, or the like. A NH₃ gas does not exist. Therefore, the Si₂Cl₆ gas does not cause a gas phase reaction and undergoes a surface reaction (chemical adsorption) with the surface of the wafer 200 or the surface of a base film to form an adsorption layer of a precursor (Si₂Cl₆) or a Si layer (hereinafter referred to as Si-containing layer). The adsorption layer of Si₂Cl₆ includes a discontinuous adsorption layer as well as a continuous adsorption layer of precursor molecules. The Si layer includes not only a continuous layer composed of Si but also a Si thin film formed by overlapping continuous layers. A continuous layer composed of Si may be referred to as a Si thin film.

At the same time, if the valve 310a is opened to allow the inert gas to flow from the carrier gas supply pipe 232a connected to the gas supply pipe 232c, it is possible to prevent the Si₂Cl₆ gas from entering the NH₃ gas supply side, which will be described later. The supply flow rate of the N₂ gas controlled by the mass flow controller 241a of the carrier gas supply pipe 232a connected to the gas supply pipe 232c is, for example, 0.1 slm.

### (Step 12)

The valve 310b of the gas supply pipe 232b is closed to stop the supply of the Si₂Cl₆ gas into the process chamber 201. At this time, while maintaining the APC valve 242 of the exhaust pipe 231 in an opened state, the inside of the process chamber 201 is exhausted by 20 Pa or less by the vacuum pump 246, and the residual Si₂Cl₆ is removed from the inside of the process chamber 201. At this time, if an inert gas such as N₂ or the like is supplied into the process chamber 201, the effect of removing the residual Si₂Cl₆ is further enhanced.

### (Step 13)

In step 13, an NH₃ gas is allowed to flow. The NH₃ gas is allowed to flow through the gas supply pipe 232c, and the carrier gas (N₂ gas) is allowed to flow through the carrier gas supply pipe 232a connected to the gas supply pipe 232c. The valve 310c of the gas supply pipe 232c, the valve 310a of the carrier gas supply pipe 232a, and the APC valve 242 of the exhaust pipe 231 are all opened. The carrier gas is allowed to flow from the carrier gas supply pipe 232a and is flow-rate-adjusted by the mass flow controller 241a. The NH₃ gas is allowed to flow from the gas supply pipe 232c, is flow-rate-adjusted by the mass flow controller 241c, is mixed with the flow-rate-adjusted carrier gas, is supplied into the process chamber 201 from the gas supply holes 234c of the nozzle 230c, and is exhausted from the exhaust pipe 231. When allowing the NH₃ gas to flow, the APC valve 242 is appropriately adjusted to maintain the pressure inside the process chamber 201 in the range of 50 to 1000 Pa, for example, at 60 Pa. The supply flow rate of the NH₃ gas controlled by the mass flow controller 241c is 1 to 10 slm. The time for exposing the wafers 200 to the NH₃ gas is 10 to 30 seconds. The temperature of the heater 206 at this time is set to a predetermined temperature in the range of 300 degrees C. to 600 degrees C., for example, 600 degrees C.

At the same time, if the opening/closing valve 310a is opened to allow the inert gas to flow from the carrier gas supply pipe 232a connected to the gas supply pipe 232b, it is possible to prevent the NH₃ gas from entering the Si₂Cl₆ gas supply side.

By supplying the NH₃ gas, the Si-containing layer chemically adsorbed on the wafer 200 and the NH₃ undergo a surface reaction (chemical adsorption) to form a SiN film on the wafer 200.

### (Step 14)

In step 14, the valve 310c of the gas supply pipe 232c is closed to stop the supply of the NH₃ gas. Further, while maintaining the APC valve 242 of the exhaust pipe 231 opened, the process chamber 201 is exhausted by 20 Pa or less by the vacuum pump 246, and the residual NH₃ gas is removed from the process chamber 201. At this time, if an inert gas such as a N₂ gas or the like is supplied to the process chamber 201 from the gas supply pipe 232c, which is on the NH₃ gas supply side, and the gas supply pipe 232b, which is on the Si₂Cl₆ gas supply side, respectively, the effect of removing the residual NH₃ gas is further enhanced.

A SiN film having a predetermined film thickness is formed on the wafer 200 by performing a cycle including steps 11 to 14 at least once. In this case, in each cycle, as described above, it is necessary to carefully perform the processing such that the atmosphere formed by the Si precursor gas in step 11 and the atmosphere formed by the nitriding precursor gas in step 13 are not mixed in the process chamber 201.

Further, the film thickness of the SiN film may be adjusted to about 1 to 5 nm by controlling the number of cycles. The SiN film formed at this time becomes a dense continuous film having a smooth surface.

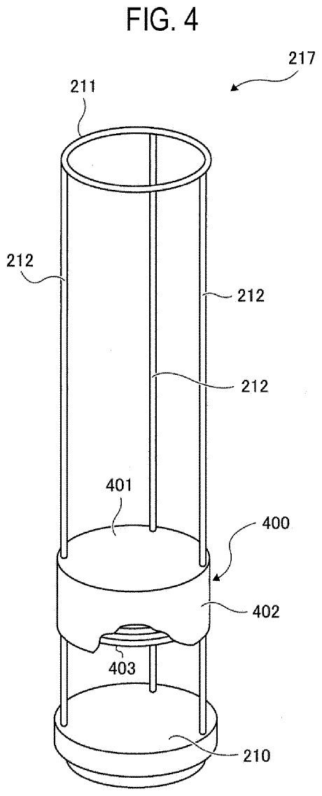

Next, the boat 217 and the inner tube 204 accommodating the boat 217 will be described in more detail with reference to FIGS. 4, 5, 6A, and 6B.

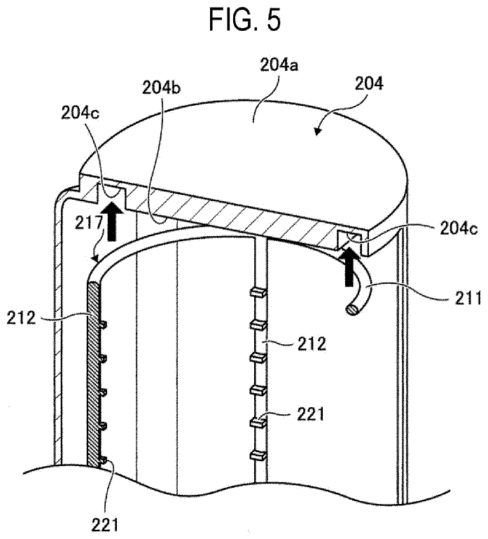

As described above, as shown in FIG. 4, the boat 217 includes a plurality of pillars 212 having substantially the same length, installed around the arranged wafers 200, and extending in a direction substantially perpendicular to the wafers 200, a ring-shaped top plate 211 having an opening at the center thereof and configured to fix the upper ends of the pillars 212 to each other, and a disk-shaped bottom plate 210 configured to fix the lower ends of the pillars 212 to each other. That is, three pillars 212 are installed between the bottom plate 210 and the top plate 211 of the boat 217 at intervals of approximately 90 degrees. The boat 217 is designed to have sufficient strength against the stress applied when erecting the boat 217, which lies down, by grasping a determined location and the stress applied when raising and transferring the boat 217. Further, as shown in FIG. 5 (not shown in FIG. 4), each pillar 212 is provided with a plurality of support pins 221 as support members for holding the wafers 200 substantially horizontally. Each support pin 221 is provided so as to extend substantially horizontally toward the inner circumference from each of the three pillars 212. In addition, the support pins 221 are provided on each of the three pillars 212 at predetermined intervals (pitch).

The cover 400 includes a top plate 401 and a cylindrical side plate 402. A disk-shaped quartz plate 403 is arranged inside the cover 400 as a substitute for a dummy substrate. The top plate 401 may be airtightly welded to the pillars 212 penetrating the holes thereof and may be seamlessly welded to the side plate 402 over the entire circumference. The quartz plate 403 may be welded to the pillars 212 before the cover 400 is installed. The cover 400 may have a bottom surface. However, in that case, a gas outlet is provided in the bottom surface so that the inside of the cover 400 is not sealed. The side plate 402 may be divided into three pieces in order to avoid interference with the pillars 212.

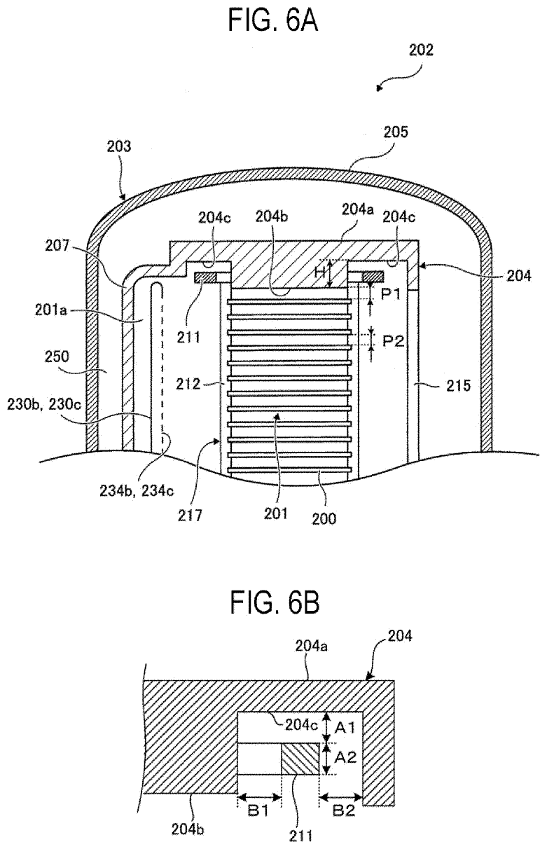

The inner tube 204 includes a ceiling 204a closed at the upper end thereof and terminates the upper portion of the inner tube 204 at the end of the direction in which the wafers 200 are stacked and arranged. The outer surface side (upper surface side) of the ceiling 204a has a flat shape. The inner surface of the ceiling 204a is provided with a protrusion 204b as a protrusion portion that protrudes inward in a cylindrical shape. The protrusion 204b has a cylindrical shape with a flat leading end. It can be said that the protrusion 204b has a shape in which the leading end portion is extruded along the arrangement axis of the wafers 200. An annular recess (groove) 204c is formed around the protrusion 204b between the outer peripheral surface of the inner tube 204 and the protrusion 204b. As shown in FIG. 6A, the protrusion 204b is smaller than the opening of the top plate 211 of the boat 217. In other words, the outer diameter of the protrusion 204b is smaller than the inner diameter of the top plate 211. Further, the inner diameter of the recess 204c is smaller than the inner diameter of the top plate 211. Further, the outer diameter of the recess 204c is larger than the outer diameter of the top plate 211. In other words, the entire inner surface of the ceiling 204a of the inner tube 204 is formed along the shape of the upper end (top plate 211) of the boat 217 with a predetermined margin (clearance).

That is, the inner surface of the ceiling 204a of the inner tube 204 has a shape corresponding to the shape of the opening of the top plate 211. In a state in which the inner tube 204 accommodates the boat 217, the top plate 211 of the boat 217 is fitted into the recess 204c of the inner tube 204 so that the top plate 211 is arranged in the recess 204c. That is, in a state in which the inner tube 204 accommodates the boat 217, the protrusion 204b of the inner tube 204 is inserted and fitted into the opening of the top plate 211 of the boat 217. If the top plate 211 has a square cross section because it is a ring having a rectangular cross section (a rotation body obtained by rotating a rectangle about a wafer arrangement axis), the corners of the recess 204c are also square. In the inner tube 204, which requires almost no mechanical strength, it is not necessary to greatly round the corners in order to avoid stress concentration. Therefore, the recess 204c may faithfully follow the shape of the top plate 211. If the pillars 212 protrude from the lower surface of the top plate 211, they may be regarded as a part of the top plate 211. Similarly, if the pillars 212 protrude from the upper surface of the bottom plate 210, those portions may be regarded as a part of the bottom plate 210. As shown in FIGS. 2, 6A and 6B, the protrusion 204b is provided at a position where protrusion 204b can be inserted into the opening of the top plate 211 in a state in which the inner tube 204 accommodates the boat 217. At this time, the opening of the top plate 211 and the protrusion 204b of the inner tube 204 are formed in a circular shape concentric with the rotary shaft 255.

Further, as shown in FIG. 6A, the height H of the protrusion 204b is set such that, in a state in which the boat 217 holding the wafers 200 stacked thereon is airtightly accommodated in the inner tube 204, that is, when the wafers 200 are processed in the inner tube 204, the distance P1 between the leading end of the protrusion 204b and the wafer 200 located closest to the top plate 211 and facing the protrusion 204b is substantially equal to the distance P2 between the wafers 200 adjacent to each other in the boat 217, that is, the pitch between the wafers 200. That is, the height H of the protrusion 204b is set such that, when the O-ring 220b has a predetermined crushing amount capable of sealing, the distance P1 between the protrusion 204b and the wafer 200 arranged closest to the top plate 211 is substantially equal to the distance P2 between adjacent wafers 200 in the boat 217. Further, the height H of the protrusion 204b is set such that, when the O-ring 220b has a predetermined crushing amount capable of sealing, the distance between the protrusion 204b and the dummy substrate arranged closest to the top plate 211 is sufficiently smaller than the distance P2 between the wafers 200 adjacent to each other in the boat 217 and larger than the variation in the predetermined crushing amount. In addition, the protrusion 204b is provided so as to be inserted into the opening of the top plate 211 in a state in which the boat 217 is accommodated in the reaction tube 203 and is configured to be closer to the wafer 200 arranged closest to the top plate 211 of the boat 217 than the top plate 211.

By configuring as described above, the top plate 211 of the boat 217 forms a narrow gap around the protrusion 204b of the inner tube 204 and in the recess 204c such that the boat 217 can be raised and rotated. This makes it possible to reduce the excess gas space above the boat 217.

By reducing the excess gas space above the boat 217 in this way, the variation in the supply amount of the process gas supplied to the wafers 200 arranged in the vertical direction on the boat 217 can be suppressed, and the partial pressures of the process gas supplied to the wafers 200 arranged in the vertical direction on the boat 217 can be made equal to each other. That is, it is possible to improve the inter-plane uniformity of the wafers such as product substrates having a large surface area.

Further, by providing the cover 400 below the boat 217 and above the heat insulating region on which the heat insulating plates 216 are stacked, the excess gas space in the lower portion of the boat 217 can be reduced, and the inter-plane uniformity of the wafers can be improved. In addition, the side dummy substrate is not required.

Further, in a state in which the boat 217 is accommodated in the inner tube 204, as shown in FIG. 6B, it is configured that the height H becomes larger than the sum of the distance A1 between the bottom surface of the recess 204c of the ceiling 204a of the inner tube 204 and the upper surface of the top plate 211 of the boat 217 and the thickness A2 of the top plate 211 in the height direction. Further, it is configured that the length B1 from the side surface of the protrusion 204b of the inner tube 204 to the inner peripheral surface of the top plate 211 and the length B2 from the outer peripheral surface of the top plate 211 to the inner peripheral surface of the inner tube 204 becomes substantially equal to each other. Further, it is configured that the distance A1 between the bottom surface of the recess 204c of the ceiling 204a of the inner tube 204 and the upper surface of the top plate 211 of the boat 217 becomes smaller than B1 and B2. That is, the distance A1 can be made relatively small because it is a margin for the dimensional accuracy of the boat 217 and the variation in the crushing amount of the O-ring 220a. The above-mentioned distance P1 varies depending on the crushing amount of the O-ring 220a. However, this variation is usually slight and negligible. If the film quality of the substrate placed closest to the top plate is not stable, a dummy substrate is used as the substrate. When a wafer having a surface area smaller than that of the product substrate is used as the dummy substrate, if the distance P1 is made smaller than the distance P2, for example, equal to the distance A1, it is possible to reduce the excess gas space generated above the dummy substrate.

### (4) Modification

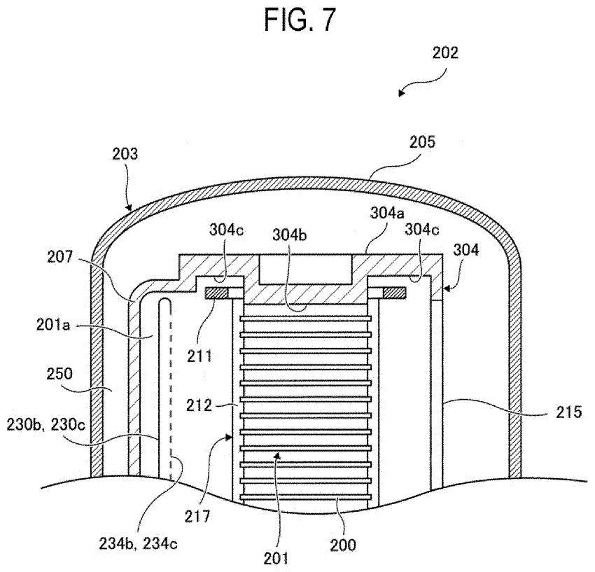

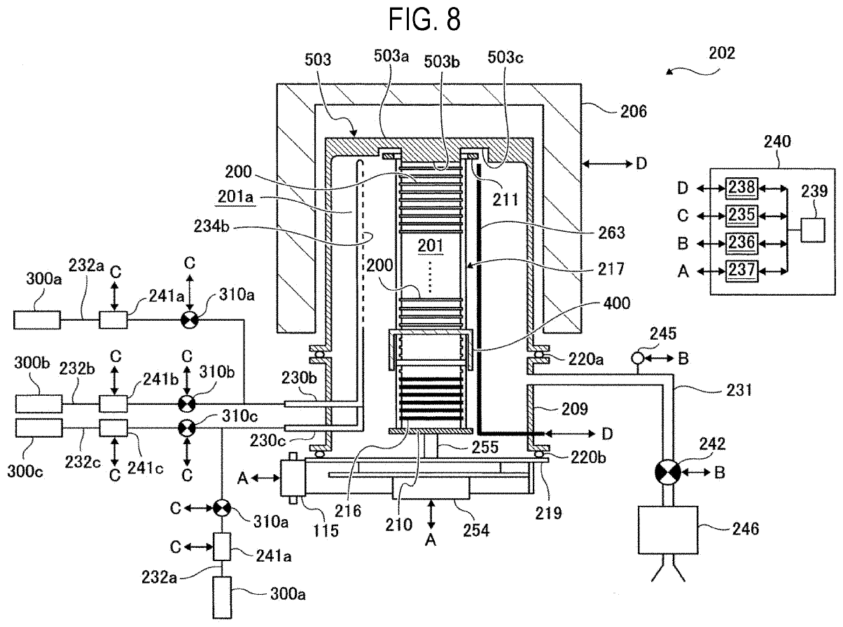

Next, a modification of the process furnace 202 according to the present embodiments will be described with reference to FIGS. 7 and 8.

The modification of FIG. 7 has a different shape from the ceiling 204a of the inner tube 204 in the above-described embodiments. In this modification, only the configuration different from the above-described inner tube 204 will be described.

The inner tube 304 according to the modification includes a ceiling 304a having a closed upper end and terminating the inner tube 304 at the end of the direction in which the wafers 200 are stacked and arranged.

The ceiling 304a includes a protrusion 304b as a protrusion portion that has an upper surface recessed inward in a cylindrical shape and in which the inner surface side of the ceiling 304a protrudes inward in a cylindrical shape. The protrusion 304b has a cylindrical shape with a flat leading end. A recess 304c is formed around the protrusion 304b and between the outer peripheral surface of the inner tube 304 and the protrusion 304b. The outer diameter of the protrusion 304b is smaller than the opening of the top plate 211 of the boat 217. In other words, the outer diameter of the protrusion 304b is smaller than the inner diameter of the top plate 211. Further, the inner diameter of the recess 304c is smaller than the inner diameter of the top plate 211. Further, it is configured that the outer diameter of the recess 304c becomes larger than the outer diameter of the top plate 211. That is, the inner surface of the ceiling 304a of the inner tube 304 has a shape corresponding to the shape of the top plate 211. When the boat 217 is accommodated in the inner tube 304, the top plate 211 is inserted into the recess 304c and arranged in the recess 304c. That is, unlike the ceiling 204a of the above-described inner tube 204 having a flat upper surface, the upper surface of the ceiling 304a of the inner tube 304 according to the modification is recessed at the center and protrudes inward in a flat manner.

As shown in FIG. 7, the protrusion 304b is provided at a position where the protrusion 304b is inserted into the opening of the top plate 211 in a state in which the boat 217 is accommodated in the reaction tube 203. That is, the protrusion 304b is provided so as to be inserted into the opening of the top plate 211 with the boat 217 accommodated in the reaction tube 203 and is configured to be closer to the wafer 200 arranged closest to the top plate 211 of the boat 217 than the top plate 211. The corners of the protrusion 304b and the recess 304c may be formed by making them angular without intentional chamfering for the same reason as in the present embodiments described above. Apart from the manufacturing difficulty and cost, the thickness of the ceiling 304a may be reduced to almost the same thickness as that of other portions of the inner tube 304.

By recessing the upper surface of the ceiling 304a to form the protrusion 304b protruding inward as in the ceiling 304a of this modification, it is possible to reduce the heat capacity as compared with the ceiling 204a according to the present embodiments described above, and it is possible to allow the heat to be easily transferred from the heater 206 into the process chamber 201.

Further, by configuring the ceiling 204a according to the present embodiments described above, it is possible to increase the heat capacity as compared with the ceiling 304a according to this modification, which makes it possible to obtain the temperature buffering effect.

By making opaque the quartz constituting the ceiling 204a according to the present embodiments and the ceiling 304a according to this modification described above, the transmittance and the thermal conductivity can be made different, which makes it difficult for the heat to be transferred from the heater 206 into the process chamber 201 or to reduce the heat capacity.

The modification of FIG. 8 includes a reaction tube 503 having a single tube structure instead of the reaction tube 203 having a double tube structure composed of the inner tube 204 and the outer tube 205 according to the present embodiments described above. In the ceiling 503a of the reaction tube 503, a protrusion 503b as a protrusion portion is formed in a convex shape similar to that of the ceiling 204a and is fitted into the opening of the top plate 211 of the boat 217. That is, the protrusion 503b is provided so as to be inserted into the opening of the top plate 211 with the boat 217 accommodated in the reaction tube 503 and is configured to be closer to the wafer 200 arranged closest to the top plate 211 of the boat 217 than the top plate 211.

### (5) Simulation

Hereinafter, the present embodiments will be described by comparison with a comparative example.

Comparison was made between a case (hereinafter referred to as Present Example) where a wafer 200 as a product substrate having an area 200 times larger than that of a bare wafer is subjected to substrate processing by the above-described method of manufacturing a semiconductor device using the process furnace 202 according to the present embodiments as shown in FIG. 2 and a case where a wafer 200 as a product substrate is subjected to substrate processing by the above-described method of manufacturing a semiconductor device using the process furnace according a Comparative Example, which differs only in that it does not have the protrusion 204b or the opening of the top plate 211.

The process furnace according to the Comparative Example has a flat shape on the inner surface side of the ceiling of the inner tube and is not provided with the protrusion 204b. Further, the top plate of the boat is disk-shaped and no opening is formed in the top plate. Further, a plurality of dummy substrates is stacked on the boat at the upper and lower ends in the arrangement direction of the wafers 200 as product substrates. That is, the cover 400 is not provided at the bottom of the boat.

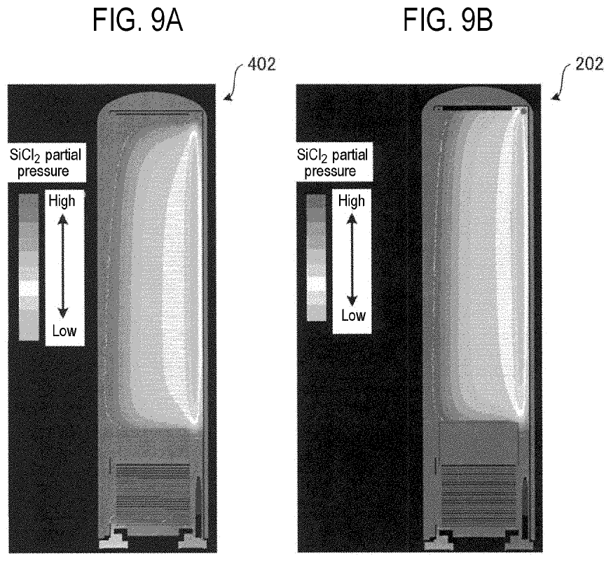

FIG. 9A is a diagram showing the distribution of a partial pressure of SiCl₂ that is a decomposition product of a Si₂Cl₆ gas in the process furnace according to the Comparative Example at the time of supplying the Si₂Cl₆ gas, and FIG. 9B is a diagram showing the distribution of a partial pressure of SiCl₂ as a decomposition product of a Si₂Cl₆ gas in the process furnace 202 according to the Present Example at the time of supplying the Si₂Cl₆ gas.

FIGS. 9A and 9B show that a Si₂Cl₆ gas is supplied from the left side. As shown in FIG. 9A, in the process furnace according to the Comparative Example, the Si₂Cl₆ gas is supplied to the wafers at a high concentration in the upper part of the process furnace (near the ceiling). On the other hand, as shown in FIG. 9B, in the process furnace 202 according to the present embodiments, the concentration of the Si₂Cl₆ gas in the upper part of the process furnace 202 (near the ceiling) is alleviated as compared with the case where the process furnace according to the Comparative Example is used. Thus, the difference in the concentration of the Si₂Cl₆ gas between the wafers is alleviated and the distribution of the partial pressure of SiCl₂ is the same in the arrangement direction of the wafers.

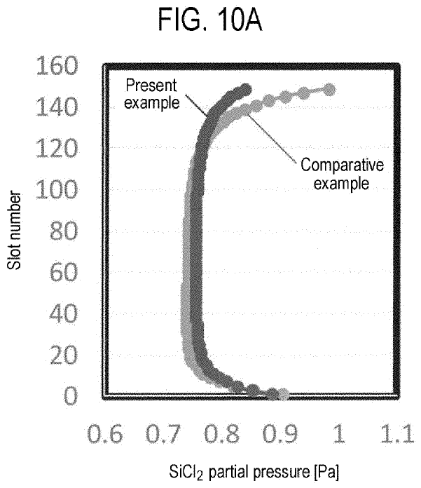

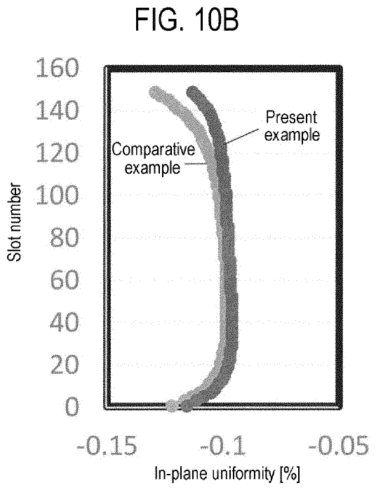

FIG. 10A is a diagram showing the wafer inter-plane uniformity that evaluates the average value of the SiCl₂ partial pressures on the wafers at the respective slot numbers. FIG. 10B is a diagram showing the wafer in-plane uniformity that compares the numerical values obtained by dividing the difference between the center and the outer periphery of each of the wafers at the respective slot numbers by an average value. As for the slot number, the larger the number, the higher the wafer is arranged in the boat 217.

As shown in FIG. 10A, when a SiN film is formed on the wafer using the process furnace according to the Comparative Example, the SiCl₂ partial pressure is higher on the wafers in the upper and lower stages of the boat than on the wafers in the middle stage. That is, the film thickness of the SiN film formed on the wafer in the upper and lower stages is larger than the film thickness of the SiN film formed on the wafer in the middle stage. Further, the difference between the maximum value and the minimum value of the SiCl₂ partial pressure is 0.242.

On the other hand, when the SiN film is formed on the wafer by using the process furnace 202 according to the Present Example, the SiCl₂ partial pressure is lowered in the upper stage of the boat 217 and the variation of the SiCl₂ partial pressure is improved, as compared with the case where the process furnace according to the Comparative Example is used. That is, the film thickness of the SiN film formed on the wafer in the upper stage is equal to the film thickness of the SiN film formed on the wafer in the middle stage. Further, the difference between the maximum value and the minimum value of the SiCl₂ partial pressure is 0.131 which is half of 0.242 which is the difference between the maximum value and the minimum value of the SiCl₂ partial pressure in the Comparative Example. That is, the inter-plane uniformity (wafer to wafer uniformity) is improved as compared with the case where the process furnace according to the Comparative Example is used.

Further, as shown in FIG. 10B, when a SiN film is formed on the wafer by using the process furnace according to the Comparative Example, the in-plane uniformity (within wafer uniformity) is deteriorated in the upper and lower stages of the boat as compared with the middle stage, and the in-plane uniformity varies in the height direction of the boat.

On the other hand, when a SiN film is formed on the wafer by using the process furnace 202 according to the Present Example, the in-plane uniformity is improved in the upper stage of the boat 217 as compared with the case where the process furnace according to the Comparative Example is used, and the variation of the in-plane uniformity in the height direction of the boat 217 is improved.

In the case of the process furnace according to the Comparative Example, an excess gas stays without consumption between the inner surface of the ceiling of the inner tube and the top plate of the boat, between the top plate of the boat and the dummy substrate, and between the dummy substrates. The gas staying without consumption invades the area where the product substrates are placed. For this reason, the amount of the process gas supplied varies in the product substrates near the top plate of the boat and the arrangement position of the dummy substrate and in the product substrates far from the top plate of the boat and the arrangement position of the dummy substrate. Therefore, the film thickness of the formed film also varies. That is, the in-plane/inter-plane uniformity deteriorates.

On the other hand, in the process furnace 202 according to the present embodiments, by narrowing the excess gas space above the boat 217, the gas capacity in the excess gas space can be reduced by about 68% as compared with the process furnace according to the Comparative Example. As a result, the SiCl₂ partial pressure can be made equal in the stacking direction of the wafers, and the inter-plane uniformity and the in-plane uniformity can be improved as compared with the process furnace according to the Comparative Example.

The above-described embodiments has the following effects. That is, the excess gas generated on the monitoring substrate or the dummy substrate consuming a reduced amount of process gas or in the gap between the top plate 211 of the boat 217 and the inner surface of the reaction tube 203 can be reduced, and the amount of the excess gas invading the area where the product substrates are placed can be reduced. Therefore, the product substrates placed in an area near the mounting area of the monitoring substrate or the dummy substrate or the top plate of the substrate holder can be prevented from being supplied with a large amount of process gas having an increased film thickness as compared with the product substrates placed in an area far from the mounting area of the monitoring substrate or the dummy substrate or the top plate 211 of the boat 217. That is, the inter-plane uniformity can be improved. Since the excess gas is supplied from the periphery (end side) of the wafer 200, it is possible to prevent the film formed on the end portion of the wafer 200 from becoming relatively thick and prevent the formed film from having deteriorated in-plane uniformity.

According to the present disclosure in some embodiments, it is possible to improve the inter-plane/in-plane uniformity of a film formed on a substrate.

While certain embodiments have been described, these embodiments have been presented by way of example only and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a substrate holder configured to arrange and hold substrates; and
a reaction tube in which the substrate holder is accommodated,
wherein the substrate holder includes:
a plurality of pillars installed around the arranged substrates and extending in a direction substantially perpendicular to the substrates;
a top plate configured to fix one ends of the plurality of pillars to each other and having an opening at a center of the top plate; and
a bottom plate configured to fix other ends of the plurality of pillars to each other,
wherein the reaction tube includes a protrusion protruding inward in a shape corresponding to a shape of the opening of the top plate and having a flat leading end, and
wherein the protrusion is installed to be inserted into the opening of the top plate in a state where the substrate holder is accommodated in the reaction tube, and is configured to be closer to a substrate arranged closest to the top plate of the substrate holder than the top plate.

2. The substrate processing apparatus of claim 1, wherein a height of the protrusion is set such that a distance between the protrusion and the substrate arranged closest to the top plate on the substrate holder is substantially equal to a distance between the substrates adjacent to each other on the substrate holder.

3. The substrate processing apparatus of claim 1, wherein the reaction tube includes:
an inner tube configured to accommodate the substrate holder; and
an outer tube having a pressure-resistant structure and configured to accommodate the inner tube,
wherein the inner tube includes a ceiling terminating an upper portion of the inner tube, and
wherein the protrusion is installed at the ceiling.

4. The substrate processing apparatus of claim 3, further comprising:
a nozzle extending parallel to an arrangement direction of the substrates and configured to supply a gas to each of the arranged substrates,
wherein the inner tube further includes a bulging portion formed by bulging outward on a side surface of the inner tube and configured to accommodate the nozzle in the bulging portion.

5. The substrate processing apparatus of claim 1, further comprising:
a rotary shaft configured to rotatably support the substrate holder,
wherein the opening and the protrusion are formed in a circular shape concentric with the rotary shaft.

6. The substrate processing apparatus of claim 1, further comprising:
a cover configured to surround a plurality of arrangement positions including an arrangement position closest to the bottom plate among arrangement positions of the substrates on the substrate holder, from an upper surface and a side surface of the plurality of arrangement positions,
wherein the substrate holder is configured to hold a plurality of product substrates or monitoring substrates at a plurality of arrangement positions between the cover and the top plate without holding the plurality of product substrates and the monitoring substrates at the plurality of arrangement positions surrounded by the cover.

7. The substrate processing apparatus of claim 4, further comprising:
a cover configured to surround a plurality of arrangement positions including an arrangement position closest to the bottom plate among arrangement positions of the substrates on the substrate holder, from an upper surface and a side surface of the plurality of arrangement positions,
wherein the nozzle includes a plurality of gas supply ports at positions corresponding to a plurality of product substrates or monitoring substrates held at a plurality of arrangement positions between the cover and the top plate without having gas supply ports at positions corresponding to the plurality of arrangement positions surrounded by the cover.

8. The substrate processing apparatus of claim 3, wherein an entire inner surface of the ceiling of the inner tube is formed along a shape of the top plate of the substrate holder.

9. The substrate processing apparatus of claim 1, further comprising:
a lid configured to close an opening through which the substrate holder is loaded into and unloaded from a process vessel constituted by the reaction tube;
a rotation mechanism installed on the lid to hold the substrate holder in the reaction tube; and
a sealing member configured to seal a gap between the reaction tube and the lid without allowing the reaction tube to directly contact the lid,
wherein a height of the protrusion is set such that, when the sealing member has a predetermined crushing amount capable of sealing, a distance between the protrusion and the substrate arranged closest to the top plate is substantially equal to a distance between the substrates adjacent to each other in the substrate holder.

10. The substrate processing apparatus of claim 1, further comprising:
a lid configured to close an opening through which the substrate holder is loaded into and unloaded from a process vessel constituted by the reaction tube;
a rotation mechanism provided on the lid to hold the substrate holder in the reaction tube; and
a sealing member configured to seal a gap between the reaction tube and the lid without allowing the reaction tube to directly contact the lid,
wherein a height of the protrusion is set such that, when the sealing member has a predetermined crushing amount capable of sealing, a distance between the protrusion and the substrate arranged closest to the top plate is sufficiently smaller than a distance between the substrates adjacent to each other in the substrate holder and larger than a variation of the predetermined crushing amount.

11. The substrate processing apparatus of claim 6, wherein the substrate holder is configured to hold the plurality of product substrates or the monitoring substrates at a plurality of arrangement positions between the cover and the top plate excluding the arrangement position closest to the top plate.

12. A reaction tube in which a substrate holder is accommodated, comprising:
a protrusion that protrudes inward in a shape corresponding to a shape of an opening of a top plate of the substrate holder configured to arrange and hold substrates, and has a flat leading end,
wherein the protrusion is installed to be inserted into the opening of the top plate in a state where the substrate holder is accommodated in the reaction tube, and protrudes inward such that the protrusion is closer to a substrate arranged closest to the top plate of the substrate holder than the top plate.

13. A method of manufacturing a semiconductor device, comprising:
accommodating a substrate holder, which is configured to arrange and hold substrates and includes a plurality of pillars installed around the arranged substrates and extending in a direction substantially perpendicular to the substrates, a top plate configured to fix one ends of the plurality of pillars to each other and having an opening at a center of the top plate, and a bottom plate configured to fix other ends of the plurality of pillars to each other, into a reaction tube which includes a protrusion protruding inward in a shape corresponding to a shape of the opening of the top plate and having a flat leading end; and
processing the substrates in the reaction tube,
wherein in the act of accommodating the substrate holder, the protrusion is inserted into the opening of the top plate and is brought closer to a substrate arranged closest to the top plate of the substrate holder than the top plate.

14. A non-transitory computer-readable recording medium storing a program that causes, by a computer, a substrate processing apparatus to perform the method of claim 13.
